(19) United States
(12) Patent Application Publication
(10) Pub. No.: US 2002/0197823 A1
(43) Pub. Date: Dec. 26, 2002

(54) Isolation method for semiconductor device

(76) Inventors: Jae-yoon Yoo, Seoul (KR); Moon-han Park, Yongin-city (KR); Dong-ho Ahn, Suwon-city (KR); Sug-hun Hong, Suwon-city (KR); Kyung-won Park, Suwon-city (KR); Jeong-soo Lee, Yongin-city (KR)

Correspondence Address: HARNESS, DICKEY & PIERCE, P.L.C., P.O. BOX 8910, RESTON, VA, 20195, US

(21) Appl. No.: 10/147,326

(22) Filed: May 17, 2002

(30) Foreign Application Priority Data
May 18, 2001 (KR) 2001-0027345
Sep. 28, 2001 (KR) 2001-60554

(51) Int. Cl. H01L 21/76

(52) U.S. Cl. 438/424

(57) ABSTRACT

An isolation method for a semiconductor device where an insulating mask layer is formed on desired regions of a semiconductor substrate. A trench is formed to a desired depth in the semiconductor substrate using the insulating mask layer as a mask. An oxide layer is formed on the insulating mask layer and on the sidewall of the trench. A trench liner layer is formed on the oxide layer. An insulating filler layer is formed in the trench in the semiconductor substrate, on which the trench liner layer is formed, so as to fill the trench. The insulating mask layer is removed. According to the isolation method for a semiconductor device, it is possible to reduce dents from occurring along the edge of the trench, reduce a bird's beak type oxide layer from occurring at an interface between the insulating mask layers, decrease the leakage current, or improve the electrical characteristics, such as threshold voltage.

### CROSS-REFERENCE TO RELATED APPLICATIONS

This U.S. nonprovisional patent application claims priority under 35 U.S.C. §119 of Korean Patent Application 2001-0027345 filed on May 18, 2001 and Korean Patent Application 2001-0060554 filed on Sep. 28, 2001, the entire contents of both of which are hereby incorporated by reference.

### BACKGROUND OF THE INVENTION

1. Field of the Invention

The present invention relates to an isolation method for a semiconductor device, and more particularly, to shallow trench isolation (STI) for isolating individual devices by forming a trench to a desired depth in a semiconductor substrate.

2. Description of the Related Art

As the integration density of semiconductor devices increases, a distance among individual devices decreases. Accordingly, an isolation distance required to electrically isolate individual devices from one another decreases considerably. There are many techniques for isolating devices. A conventional isolation technique, local oxidation of silicon (LOCOS), was applied to dynamic random access memories (DRAM) after 64M having a design rule no greater than 0.40 μm. However, in recent years, a trench technique for isolating devices by etching a portion of a semiconductor substrate to form a trench, such as shallow trench isolation (STI) which forms a trench to a depth no greater than 3 μm, has been widely applied to semiconductor devices. Particularly, the STI technique has been applied to semiconductor devices having a design rule no greater than 0.15 μm (256 M DRAM production version) without any serious problems.

In order to form a trench by a conventional STI technique, a nitride mask layer is partially formed on a silicon substrate, on which devices will be formed. A portion of the semiconductor substrate, where a trench will be formed, is left uncovered with the intrude mark and the silicon substrate is etched to form a trench. Then, an insulating silicon nitride layer acting as a STI liner layer is formed in the trench, and a silicon oxide layer is deposited to fill the trench. The insulating silicon nitride layer is planarized to be level with the silicon substrate so that the silicon insulating layer is left only in the trench and thus a device isolation region is defined. The silicon nitride layer remaining on the regions where devices will be formed is removed, and the device isolation process is completed. In order to remove the silicon nitride layer remaining on the regions where devices will be formed, a wet etching method using phosphoric acid (H₃PO₄) at a high process temperature may be employed. However, in most cases, due to the characteristics of wet etching, all layers exposed to the etching solution are slightly etched and worn out at different etching rates. Thus, in a case where layers to be exposed to the wet etching process are formed of the same material as the insulating silicon nitride layer, which is a STI liner layer, the layer and the STI liner layer are isotropically etched at the same time. In addition, in a case where layers to be exposed to the wet etching process are introduced for maintaining the electrical properties of a transistor and the thickness of the silicon oxide layer filling the trench, the layer may be damaged by the wet etching process. Moreover, since a chemical reaction occurs more vigorously at a crevice between different layers than at the surface of a material, dents may occur along the border between each of the regions of the semiconductor substrate on which devices will be formed and the trench and thus may increase leakage current and cause a hump phenomenon concerning the electrical characteristics of the transistor. In addition, in a case where patterns are formed on a conductive layer (such as conductive polycrystalline silicon) in a subsequent process, the conductive layer existing in the dents may still remain after removing the conductive layer so that electrical defects, such as a short fail, may be caused.

### SUMMARY OF THE INVENTION

At least one exemplary embodiment of the present invention provides an isolation method for a semiconductor device for reducing the possibility of dents occurring along the border between each of the regions of the semiconductor substrate on which devices will be formed and the trench during a shallow trench isolation (STI) process of a semiconductor device.

At least one exemplary embodiment of the present invention provides an isolation method for a semiconductor device for decreasing leakage current without a hump phenomenon concerning the electrical characteristics of a transistor.

In at least one exemplary embodiment of the present invention, there is provided an isolation method for a semiconductor device. An insulating mask layer pattern is formed on regions of a semiconductor substrate. A trench is formed to a predetermined depth in the semiconductor substrate using the insulating mask layer pattern as a mask. An oxide layer is formed on the insulating mask layer pattern and on the sidewall of the trench. A trench liner layer is formed on the oxide layer.

An insulating filler layer is formed in the trench on the semiconductor substrate on which the trench liner layer is formed so as to fill the trench. The insulating mask layer pattern is removed.

In the step of forming an insulating mask layer pattern, a pad oxide layer is formed on the semiconductor substrate through dry oxidation, and a silicon nitride mask layer is formed on the pad oxide layer by low pressure chemical vapor deposition (LP CVD).

In order to form a trench pattern on the insulating mask layer, photoresist is coated on the insulating mask layer, and a trench pattern is formed through a photolithographic process, and the trench pattern is formed on a lower portion of the insulating mask layer by dry etching using the photoresist as a mask. In this case, in order to reduce process obstacles caused by reflection of light of the insulating layer before the photoresist is coated on the insulating mask layer, an antireflection layer formed of silicon nitride or silicon oxynitride may be further formed. In addition, when the trench pattern is formed on the insulating mask layer, the pad oxide layer may be removed so that the semiconductor substrate is exposed. After the trench pattern is formed on the insulating mask layer, the photoresist may be completely removed.

In the step of forming a trench in the semiconductor substrate, silicon is etched to the depth between 0.1 μm and 1 μm by dry etching, using the insulating mask layer pattern as a mask. In this case, in a case where the trench is etched while making the photoresist left in the insulating mask layer pattern, the step further includes the step of removing the photoresist. An oxide protection layer for curing plasma damage to the trench in the trench etch and reducing contamination in a subsequent process may be further formed on the sidewall or inner wall of the trench. The oxide protection layer is formed by thermal oxidation, and preferably, by dry oxidation. A silicon oxide layer deposited by chemical vapor deposition may be further included.

In the step of forming the oxide layer on the surface of the insulating mask layer pattern, the oxide layer is formed by thermally oxidizing a silicon nitride layer. In the step of forming the oxide layer on the surface of the silicon nitride layer, the semiconductor substrate on which the insulating mask layer pattern is formed is heated to a desired temperature. Next, an oxide layer is formed to a desired thickness by supplying an oxidation gas on the insulating mask layer. In this case, the step of heating the semiconductor substrate is performed by rapid thermal processing. In particular, since an oxide layer is easily formed due to a higher oxidation rate in the silicon nitride layer in rapid thermal processing, the oxide layer is formed to a thickness of 20-300 Å at a temperature between 700° C. and 1100° C. The volume ratio of the hydrogen gas to the total mixed gas is 1-50%. The step of forming the oxide layer is performed under a Kr/O₂ plasma atmosphere. Additionally, the step of forming the oxide layer is performed at a pressure between 1 torr and 760 torr.

Next, the trench liner layer is formed as a protection layer so that the oxide layer in the trench is not affected by a subsequent wet cleaning or wet etching process. The trench liner layer is formed of a silicon nitride layer formed by low pressure chemical vapor deposition so that solution or impurity element is not penetrated due to comparatively high density and hardness is used as the trench liner layer. The trench liner layer may be formed of boron nitride (BN) or aluminum oxide (Al₂O₃), which can serve as a protection layer due to high density, other than the silicon nitride layer. In an exemplary embodiment, the BN is formed by one of low pressure chemical vapor deposition (LP CVD) and atomic layer deposition (ALD), and the aluminum oxide is formed by atomic layer deposition (ALD).

In the step of filling the trench with an insulating filler layer, a silicon oxide layer, which is an insulating filler layer, is formed in the trench so as to completely fill the trench. In this case, the silicon oxide layer is formed by chemical vapor deposition using plasma. Since the silicon oxide layer has low density due to its incompact structure, the silicon oxide layer is densified by heat-treating the insulating filler layer at a temperature between 800° C. and 1150° C. and under an inert gas atmosphere for a desired time. Next, the densified silicon oxide filler layer is planarized through chemical mechanical polishing and is removed, so as to make the insulating filler layer left only in the trench. In this case, the step of planarizing the insulating filler layer is performed through chemical mechanical polishing using the insulating mask layer as a polishing stopper.

After the silicon oxide filler layer in other portions other than the trench is completely removed, the silicon nitride layer used as the insulating mask layer and the pad oxide layer are etched by wet etching and is removed. In this case, in order to remove the silicon nitride layer, etching solution used for wet etching is phosphoric acid (H₃PO₄) solution and has high etching selectivity with the silicon oxide layer, and thus the silicon nitride layer used as the insulating mask layer is removed without substantially affecting the pad oxide layer. The pad oxide layer is removed using silicon oxide layer etching solution, thereby completing an isolation process.

Likewise, an isolation method for a semiconductor device according to at least one exemplary embodiment the present invention, can reduce the occurrence of dents along the edge of the trench by forming the sidewall oxide layer to a desired thickness at the sidewall of the insulating mask layer, thereby enhancing the electrical characteristics of a device concerning leakage current or threshold voltage.

In another exemplary embodiment of the present invention, there is provided an isolation method for a semiconductor device. A gate insulating layer, a gate conductive layer, and an insulating mask layer are formed in sequence on a semiconductor substrate on which silicon is exposed. The insulating mask layer, the gate conductive layer, and the gate insulating layer are patterned to form an insulating mask layer pattern and a gate. A trench is formed in the silicon of the semiconductor substrate using the insulating mask layer and the gate as a mask. A sidewall insulating layer is formed to a desired thickness on the surface of the silicon of the semiconductor substrate exposed in the trench and on the sidewall of the gate conductive layer of the gate through rapid thermal processing. The trench is filled with an insulating filler layer. The insulating mask layer is removed after the insulating filler layer is planarized, and then, a second gate is formed on the gate, thereby completing a floating gate electrode.

In the step of forming a gate insulating layer, the surface of the semicondcutor substrate is cleaned using diluted HF solution and H₂SO₄ solution and HCl solution, which are strong acid, so that impurity such as polymer and heavy metal, is removed from the surface of the semiconductor substrate. The semiconductor substrate on which silicon is exposed is oxidized by supplying an oxygen gas onto the semiconductor substrate, thereby forming the gate insulating layer. Then, a cleaned gate oxide layer is formed, thereby enhancing the electrical reliability of the gate insulating layer. The surface of the gate insulating layer is nitrified using a N₂O or NO gas as a nitrogen source gas after the silicon oxide layer is formed, thereby forming a silicon oxynitride layer (SiON), and the silicon oxynitride layer is preferable, because the reliability of the gate insulating layer which is deteriorated as the gate insulating layer is ultra thinner, is enhanced due to the silicon oxynitride layer.

After the gate insulating layer is formed, a gate conductive layer having conductivity is formed, and an insulating mask layer is formed on the gate conductive layer. The gate conductive layer is formed of Phosphorus (P) or Arsenic (As)-doped polysilicon by chemical vapor deposition, and the insulating mask layer is formed of a silicon nitride layer by plasma enhanced chemical vapor deposition (PE CVD) to a desired thickness so that the insulating mask layer is used as a mask for etching a trench in a subsequent process.

Photoresist is coated on the insulating mask layer, and a gate pattern and a trench pattern are formed on the photoresist through alignment exposure and development processes. The gate pattern are formed on the insulating mask layer and the gate conductive layer by dry etching using the photoresist on which the gate pattern and the trench pattern are formed, as a mask, and simultaneously, a mask for etching a trench is formed. In an exemplary embodiment, the lowermost portion of the gate insulating layer formed in a region contacting the semiconductor substrate is completely removed, so that the semiconductor substrate on which silicon is exposed is exposed, and thus the trench is easily etched in a subsequent trench etching process. Next, the trench is formed in the silicon of the semiconductor substrate by dry etching using the photoresist and the insulating mask layer as a mask. Polymer due to etching bi-product may occur in the trench, and thus the polymer may be removed by a subsequent cleaning process.

The sidewall insulating layer is formed to a desired thickness on the surface of the silicon of the semiconductor substrate exposed in the trench and on the sidewall of the gate conductive layer of the gate. The sidewall insulating layer is a silicon oxide layer which is formed pressure under between 0.1 torr and 700 torr, oxidized and formed at a process temperature between 800° C. and 1150° C., and to which a selected process gas (oxidant gas) is supplied. Hydrogen (H₂) gas and oxygen (O₂) gas are simultaneously used when forming the silicon oxide layer, and wet oxidation and dry oxidation are in-situ simultaneously performed on the semiconductor substrate. In this case, the hydrogen gas and the oxygen gas are supplied at the volume ratio between 1:50 and 1:5, and thus process controllability for forming a thin silicon oxide layer is high.

A silicon insulating layer is thickly formed on the entire surface of the semiconductor substrate, thereby filling the trench with an insulating filler layer. In this case, the silicon insulating layer is a silicon oxide layer and is formed by plasma enhanced chemical vapor deposition (PE CVD) using plasma having a high deposition rate and high filling characteristics. Next, the silicon oxide layer formed on the insulating mask layer is completely removed by a planarization process using chemical mechanical polishing (CMP), and the silicon oxide layer is left only in the trench, thereby completing a trench filling process.

Part of a semiconductor memory device among DRAM, SRAM, or non-volatile memory (NVM) using a single gate, is manufactured through processes of forming junctions, capacitors, and an interlevel dielectric (ILD) layer, and a metal interconnection process according to the characteristics of a semiconductor memory device to be manufactured.

A semiconductor memory device such as a flash memory or EPROM or EEPROM using a double gate, includes a process of forming a second gate as follows.

That is, after the insulating layer and the gate are formed through the trench filling process, a double second gate is formed on the gate. First, the silicon nitride layer, which is the insulating mask layer formed on the gate, is removed so that an upper portion of the gate is exposed, and an intermediate gate formed of impurity-doped polysilicon as a conductive material, and a dielectric layer is formed on the surface of the gate. A high capacitance is realized by widening an area where the second gate contacts the gate. The dielectric layer is one of TaO₅, PLZT, PZT, and BST or oxide/nitride/oxide (ONO). A second gate conductive layer is formed on the dielectric layer. The second gate conductive layer the second gate conductive layer further forms a silicide layer on the doped polysilicon. A photoresist is coated, and a second gate pattern is formed on the second gate conductive layer through alignment exposure and development processes. A gate pattern is transferred onto the second gate conductive layer using the photoresist as a mask by dry etching, thereby forming a second gate. However, the second gate has a relation with a signal processing speed of the device. In a case where the design rule of the device is ultra narrow, the impurity-doped polysilicon is not sufficient, and thus polycide, which is formed by combining metal silicide having a lower resistivity, can be applied. In this case, the silicide is formed by self-aligned silicidation in a gate pattern having a ultra narrow design rule.

When the second gate is formed after the gate is formed, and the dielectric layer is a high dielectric layer, the intermediate gate is not interposed, and the dielectric layer is formed on the upper portion of the gate, and then the second gate may be formed. Then, the number of processes is reduced, resulting in reduced manufacturing costs.

After the second gate is formed, a process of manufacturing a semiconductor memory device such as flash memory, EPROM, or EEPROM, is completed through processes of forming bit lines and contacts, and a metal interconnection process.

The semiconductor memory device can suppress the formation of bird's beaks occurring at an interface between the insulating mask layers formed on the gate, by forming the gate sidewall insulating layer on the sidewall of the gate formed simultaneously with an isolation trench pattern, using rapid thermal oxidation.

In another exemplary embodiment of the present invention, there is provided a method for forming a silicon oxide layer on a semiconductor substrate. A semiconductor substrate including regions on which silicon or polysilicon is exposed is prepared. The semiconductor substrate is maintained at a low pressure atmosphere. The semiconductor substrate is rapid-thermal-heated at a desired process temperature. A reaction gas containing an oxygen source gas and a hydrogen source gas is supplied onto the semiconductor substrate and forming a silicon oxide layer on the regions on which the silicon or polysilicon is exposed, by a combined oxidation reaction of wet oxidation and dry oxidation.

The exposed region is one of the sidewall of a gate and the sidewall of a trench.

The low pressure is between 0.1 torr and 700 torr.

The process temperature is between 800° C. and 1150° C.

The reaction gas is a mixed gas of oxygen (O₂) as an oxygen source gas and hydrogen (H₂) as a hydrogen source gas at a desired ratio, and the oxygen gas and the hydrogen gas are supplied at the volume ratio between 1:50 and 1:5, and the oxygen gas is supplied at the flow rate between 1 slm and 10 slm.

The hydrogen source gas is one of deuterium (D₂) or tritium (T₂), and the oxygen source gas is one of N₂O and NO.

The reaction gas further includes an inert atmosphere gas, and the atmosphere gas is one of nitrogen (N₂), argon (Ar), and helium (He).

In the isolation method for a semiconductor device in at least one exemplary embodiment of the present invention, the silicon oxide layer is formed in silicon or polysilicon of the semiconductor substrate using rapid thermal oxidation, thereby a time for exposing the oxidation reaction gas is short by forming the silicon oxide layer for a short time, and owing to natural dispersion, the oxidation gas doesn't move to the interface, and thus the formation of bird's beaks occurring at the interface between the insulating mask layers formed on the gate can be suppressed.

### BRIEF DESCRIPTION OF THE DRAWINGS

The present invention will become more apparent by describing in detail exemplary embodiments thereof with reference to the attached drawings in which:

FIG. 1 is a cross-sectional view illustrating an isolation region for a semiconductor device according to an exemplary embodiment of the present invention;

FIGS. 2 through 9 are cross-sectional views illustrating a method for isolating individual devices for a semiconductor device according to an exemplary embodiment of the present invention;

FIG. 10 is a unit process flow chart illustrating a method for forming a silicon oxide layer on a silicon nitride layer according to an exemplary embodiment of the present invention;

FIGS. 11 through 18 are cross-sectional views illustrating a method for manufacturing a semiconductor device according to another exemplary embodiment of the present invention;

FIGS. 19 through 21 are cross-sectional views illustrating a method for manufacturing a semiconductor device according to another exemplary embodiment of the present invention;

FIG. 22 is a process flow chart illustrating a method for forming a silicon oxide layer on a semiconductor substrate according to another exemplary embodiment of the present invention;

FIG. 23 is a schematic view illustrating a rapid thermal processor used for forming a silicon oxide layer on a semiconductor substrate according to another exemplary embodiment of the present invention;

FIGS. 24A and 24B are photographs taken by scanning electron microscope (SEM), which illustrate a section after formation of a gate sidewall oxide layer according to another exemplary embodiment of the present invention and a section after formation of a gate sidewall oxide layer in the prior art; and

FIGS. 24C and 24D are cross-sectional views illustrating FIGS. 24A and 24B.

### DETAILED DESCRIPTION OF THE INVENTION

The present invention will now be described more fully with reference to the accompanying drawings, in which exemplary embodiments of the invention are shown. This invention may, however, be embodied in many different forms and should not be construed as being limited to the exemplary embodiment set forth herein. Rather, these exemplary embodiments are provided so that this disclosure will be thorough and complete, and will fully convey the concept(s) of the present invention to those skilled in the art.

FIG. 1 is a cross-sectional view illustrating a semiconductor device, to which an isolation method for a semiconductor device according to at least one exemplary embodiment of the present invention has been applied. As illustrated in FIG. 1, the semiconductor device according to at least one embodiment of the present invention includes a trench 110 recessed to a desired depth in a semiconductor substrate 100. An insulating mask layer 103, in which a pad oxide layer 101 and a silicon nitride layer 102 are sequentially deposited, is formed as a mask on the surface of portions of the semiconductor substrate 100 which is not occupied by the trench 110. An oxide layer 105 is formed as a protection layer on the sidewall and bottom of the trench 110. A sidewall protection layer 107 is formed on the sidewall of the insulating mask layer 103. A trench liner layer 109 is formed of silicon nitride to a desired thickness on the oxide layer 105 and the sidewall protection layer 107. A silicon oxide layer 111 is formed to fill the trench 110.

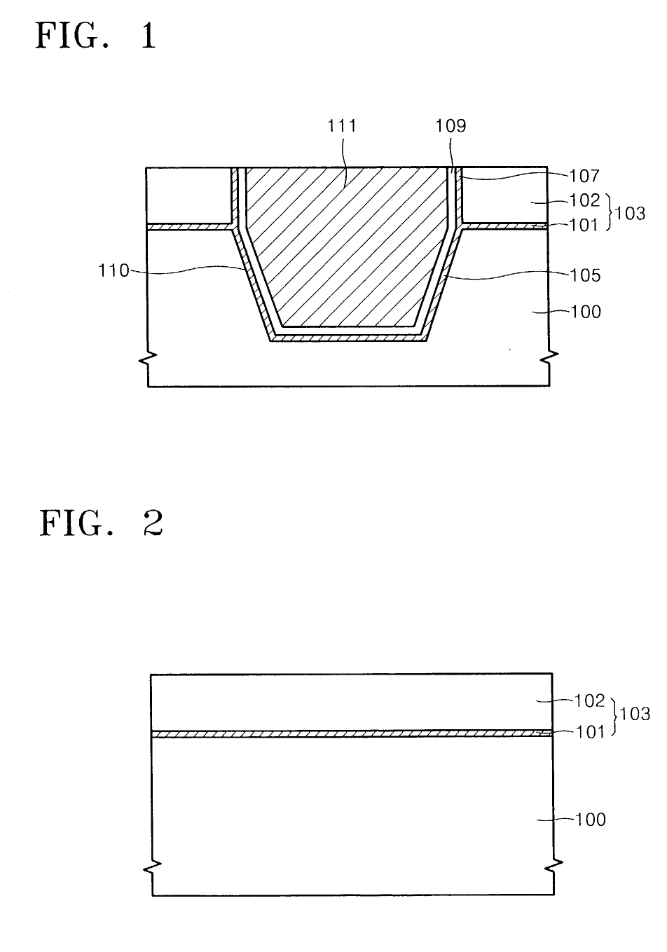

FIGS. 2 through 9 are cross-sectional views illustrating an exemplary method for isolating individual devices for the semiconductor device shown in FIG. 1. Referring to FIG. 2, the pad oxide layer 101 and the silicon nitride layer 102 are sequentially formed on the semiconductor substrate 100 to form the insulating mask layer 103. In one exemplary embodiment, the pad oxide layer 102 is formed by thermal oxidation in that silicon of the semiconductor substrate 100 reacts with oxygen or vaporizing water (H₂O) so as to be oxidized. The thermal oxidation is performed at a process temperature of 900-950° C. The silicon nitride layer 102 is formed to a thickness of 500-1500 μm by chemical vapor deposition (CVD). The silicon nitride layer 102 is formed to have high density and good hardness and show superior mechanical characteristics by using low pressure chemical vapor deposition (LP CVD). However, when very fine patterns are transferred to photoresist, which will be formed later by applying light on the insulating mask layer 103 in an alignment exposure process after forming the insulating mask layer 103, the patterns may not be finely formed on the photoresist due to irregular light reflection occurring on the surface of the insulating mask layer 103. In other words, the critical dimension of the patterns may not be good. Accordingly, in order to reduce light reflection on the surface of the insulating mask layer 103, an anti-reflection layer may be further formed on the insulating mask layer 103. The anti-reflection layer may be formed of a silicon nitride layer by plasma enhanced CVD or a silicon oxynitride layer to a desired thickness.

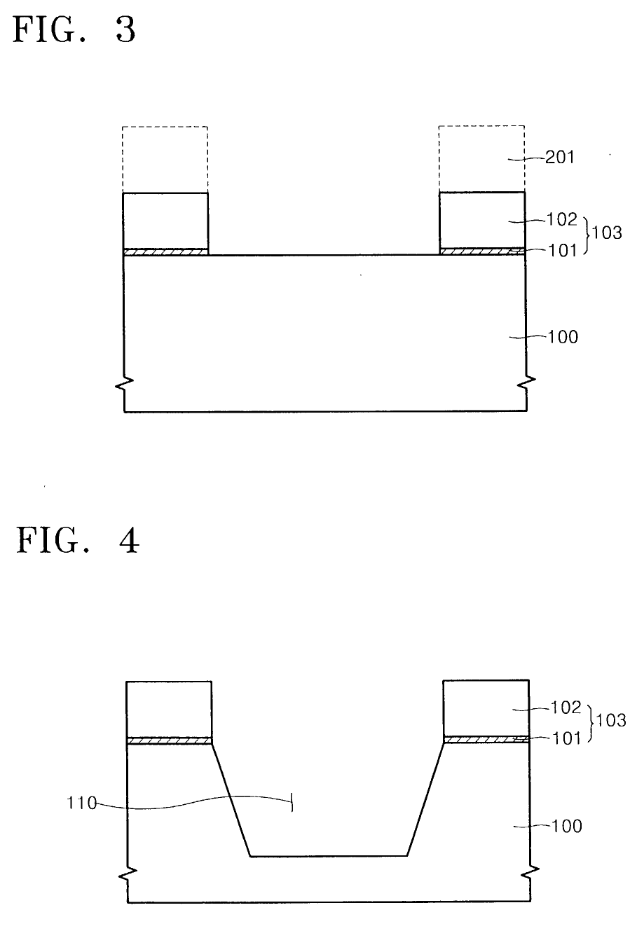

Referring to FIG. 3, photoresist is coated on the silicon nitride layer 102, undergoes an alignment and exposure process using a stepper, which includes a reticle on which a trench pattern is formed, and is developed by using a developer, thereby forming the photoresist layer 201 at which a trench pattern is formed. Then, the insulating mask layer 103 is etched by dry etching, thereby forming the trench pattern. In one exemplary embodiment, the insulating mask layer 103 is anisotropically dry-etched by reactive ion etching or plasma enhanced dry etching. The insulating mask layer 103 may be dry-etched in at least two different ways. A first way is that only the silicon nitride layer 102 is etched with the pad oxide layer 101 under the silicon nitride layer 102 left. A second way is that the silicon nitride layer 102 and the pad oxide layer 101 are etched so as to expose the silicon of the semiconductor substrate 100.

Referring to FIG. 4, the silicon of the semiconductor substrate 100 is recessed to a desired depth using the insulating mask layer 103 to which the trench pattern is transferred as a mask, thereby forming a trench 110. The depth of the trench 110 may be in a range between 0.1 μm and 1 μm depending on the characteristics or design rule of a semiconductor device. Preferably, the trench 110 is formed to taper towards the bottom portion thereof for reducing the possibility of voids generated in a filling material being deposited in the trench 110 in a subsequent process. The trench etch may be performed with the photoresist 201 remaining on the insulating mask layer 103 or may be performed using only the insulating mask layer 103 as a mask after completely removing the photoresist 201 through a cleaning process. In order to reduce the possibility of the silicon of the semiconductor substrate 100 being contaminated by organic materials contained in the photoresist 201, the photoresist 201 may be completely removed and then the semiconductor substrate 100 is trench-etched using only the insulating mask layer 103 as a mask.

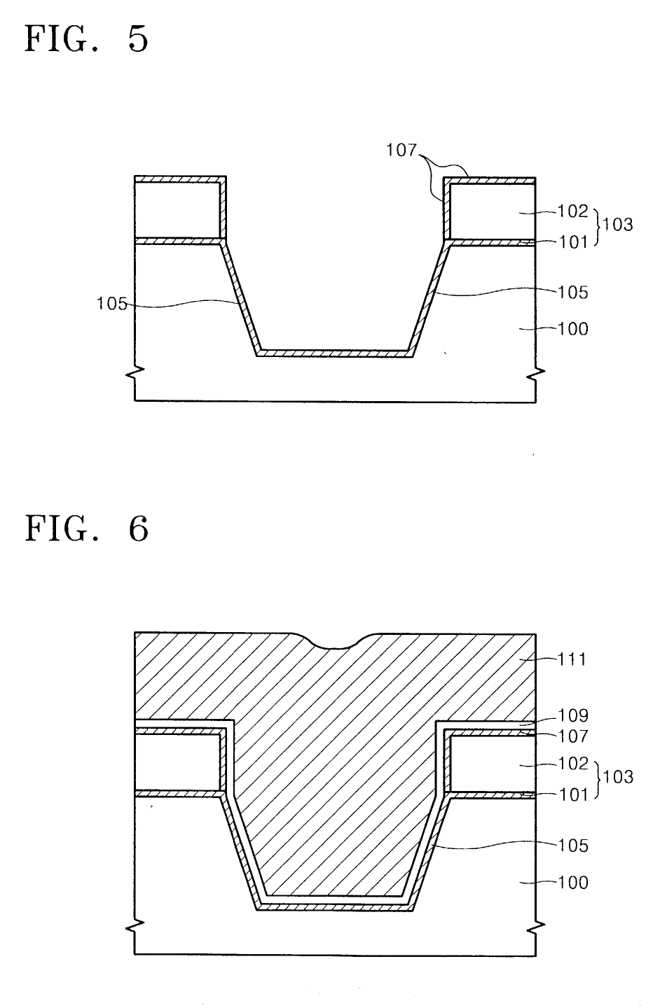

Referring to FIG. 5, the oxide protection layer 105 is formed on the sidewall and bottom of the trench 110 formed by the trench etch through thermal oxidation. The thermal oxidation is a kind of dry oxidation and forms a silicon oxide layer by supplying oxygen (O₂) gas into the trench 100 at a relatively high temperature of 950° C., during which hydrochloric acid (HCl) gas is preferably injected in order to remove contaminated metals at the region on which the silicon is exposed (this process is called clean oxidation). As a result, the oxide protection layer 105, which is not contaminated by metals, is formed in the trench 110. The oxide protection layer 105 can be hardly formed on regions at which a silicon nitride layer or a silicon oxide layer has been formed. The oxide protection layer 105 is introduced for curing plasma damage to the trench 110 in the trench etch and lessening defects introducing from the plasma damage by oxidizing the defective portions. In addition, the oxide protection layer 105 can reduce contaminants, such as transition metals or organic materials, from infiltrating into the silicon substrate in the trench 110 and acts as a buffer layer for reducing the accumulated stress of a filling insulating layer later formed to fill the trench 110 from being directly transmitted to the sidewall of the trench 110.

Next, a silicon oxide layer is formed on the surface of the insulating mask layer 103 formed of a silicon nitride layer by rapid thermal oxidation. Here, the silicon oxide layer may be formed on the sidewall of the insulating mask layer 103 and the sidewall or inner wall of the trench 110 at the same time by rapid thermal oxidation. Wet oxidation or dry oxidation may be used as the rapid thermal oxidation. In most cases, a silicon nitride layer is oxidized more easily by wet oxidation employing a rapid thermal process (RTP). The silicon oxide layer is formed on the silicon nitride layer at a process temperature between 700° C. and 1150° C. by using the RTP and supplying a mixed gas of oxygen and hydrogen showing an O₂:H₂ appropriate ratio into a reactor. In an exemplary embodiment, the volume ratio of hydrogen supplied into the reactor to the mixed total gas is about 1-50%. The pressure of the reactor may be adjusted to a range between 1 torr and 760 torr. As a result, the sidewall oxide layer 107 is formed on the sidewall and top surface of the insulating mask layer 103, and the oxide protection layer 105 becomes thicker (in a case where the oxide protection layer 105 has not been separately formed, the oxide protection layer 105 is formed at the sidewall of the trench 110 in this step). Thus, lattice strains caused by dislocation or stacking faults occurring in the formation of the trench 110 can be reduced, thereby improving the electrical characteristics of a semiconductor device after all processes required to manufacture the semiconductor device have been completed.

Referring to FIG. 6, the trench liner layer 109 is formed of a silicon nitride layer on the oxide protection layer 105 and the sidewall oxide layer 107 by low pressure chemical vapor deposition (LP CVD). The trench liner layer 109, which is formed to have a high density, reduces the possibility that the insulating filler layer 111 or the pad oxide layer 101 adjacent to the upper portion of the trench 110 will be over-etched in a subsequent wet process, such as wet cleaning or wet etching and thus reduces the occurrence of dents along the border between the insulating filler layer 111 and the pad oxide layer 101 in the trench 110.

Next, the insulating filler layer 111, which is formed of a silicon oxide layer, is thickly deposited on the trench liner layer 109 so as to fill the trench 110. The insulating filler layer 111 may be formed by low pressure chemical vapor deposition (LP CVD) or plasma-enhanced chemical vapor deposition (PE CVD) using plasma. The insulating filler layer 111 may be formed by high density plasma chemical vapor deposition (HDP CVD). An ozone tetraethylorthosilicate (TEOS(Si(OC₂H₅)₄) oxide layer, a silane-based oxide layer or an undoped silicate glass (USG) layer may be used for the insulating filler layer 111. Alternatively, a mixed layer of one of high process temperature oxide (HTO) and boro-phosphosilicate glass (BPSG) and one of ozone tetraethylorthosilicate, a silane-based oxide, and USG may be used for the insulating filler layer 111. After the insulating filler layer 111 is deposited to completely fill the trench 110, the insulating filler layer 111 is densified at a process temperature between 800° C. and 1150° C. in an inert atmosphere. Then, the insulating filler layer 111 is condensed and densified so as to have high mechanical strength and high chemical resistance. Thus, the insulating filler layer 111 cannot be etched in fluoric acid solution, such as HF or buffered HF (BHF), which is an etching solution for a silicon oxide layer used in a subsequent etching process, and can be left after the etching process, thereby reducing the possibility that the edge of the trench 110 will collapse and reduce the occurrences of voids around the center of the trench 110.

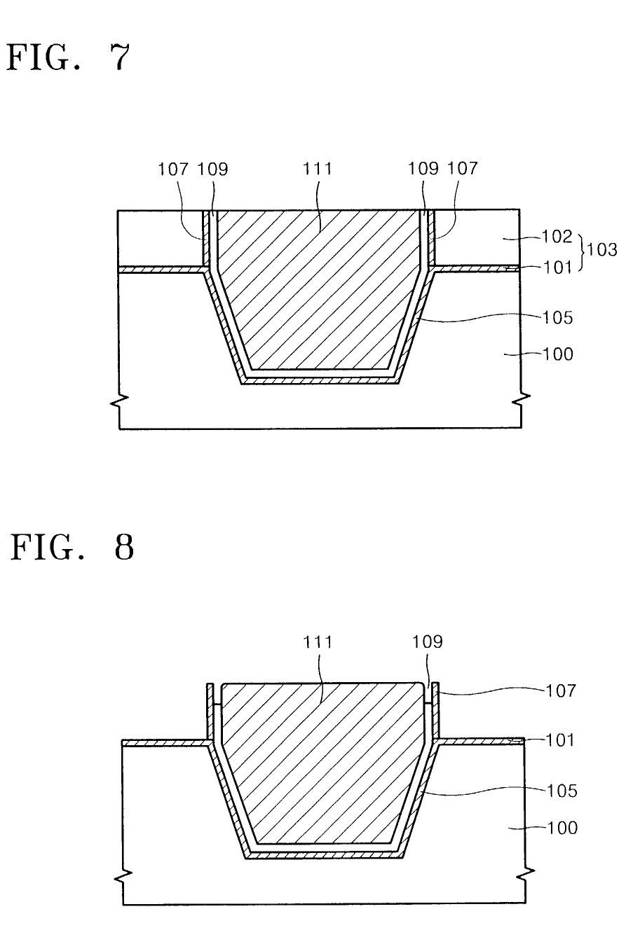

Referring to FIG. 7, the insulating filler layer 111 formed on the semiconductor substrate 100 is removed except for portions of the insulating filler layer 111 filling the trench 110. The insulating filler layer 111 is polished to be level with the silicon nitride layer 102 comprising the insulating mask layer 103 through chemical mechanical polishing. As a result, the insulating filler layer 111 can be left only in the trench 111. In the chemical mechanical polishing process, a recipe showing a low polishing selectivity of a silicon nitride layer to a silicon oxide layer may be used for the purpose of protecting the underlying layers and the silicon of the semiconductor substrate 100 placed under the silicon oxide layer 111.

Referring to FIG. 8, in order to complete the isolation process and expose the silicon of the semiconductor substrate 100, the silicon nitride layer 102 comprising the insulating mask layer 103 formed on the region on which devices are formed is removed first. The silicon nitride layer 102 may be removed by dry etching or by wet etching using an etching solution. In order to perform the etching process without causing plasma damage to the silicon of the semiconductor substrate 100, the silicon nitride layer 102 may be reduced by wet etching using phosphoric acid (H₃PO₄). If the silicon nitride layer 102 is not completely removed from the surface of the pad oxide layer 100, the pad oxide layer 101 may be etched well in a subsequent etching process. Thus, the silicon nitride layer 102 may be over-etched for about 100-200% of a reference etching time so that the silicon nitride layer 102 is completely removed from the surface of the pad oxide layer 101. Due to the etching process for removing the silicon nitride layer 102, the pad oxide layer 101 and the insulating filler layer 111 are slightly etched and worn out a little, and the trench liner layer 109, which is interpolated between the sidewall oxide layer 107 and the insulating filler layer 111, also tends to be slightly etched and recessed. However, since the etching rate of the trench liner layer 109 is very low, the depth to which the trench liner layer 109 is etched cannot reach the surface of the semiconductor substrate 100 below.

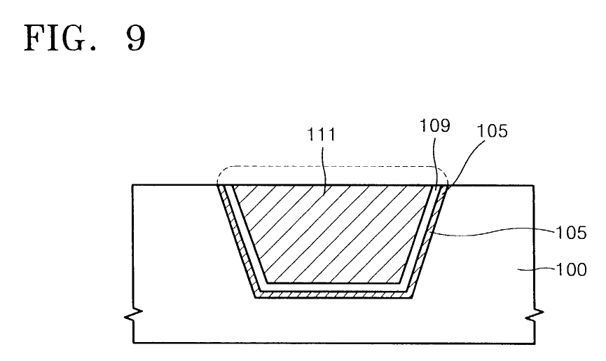

Referring to FIG. 9, the pad oxide layer remaining on the region on which a device may be placed, may be removed so as to expose the surface of the semiconductor substrate 100. The pad oxide layer may be removed by wet etching. A HF or BHF-containing solution or a diluted solution of HF or BHF may be used as an etching solution. In order to reduce water marks, which are easily formed after an etching process, from remaining on the semiconductor substrate 100, peroxide (H₂O₂) treatment may be performed on the semiconductor substrate 100 and then the semiconductor substrate 100 is dried by isopropyl alcohol (IPA) drying. During the wet etching process, the sidewall oxide layer 107 as well as the pad oxide layer 101 is etched and removed, and the insulating filler layer 111 formed of a silicon oxide layer and exposed to the outside is exposed to a desired thickness. As a result, as shown in FIG. 9, the top surfaces of the insulating filler layer 111, the trench liner layer 109, and the oxide protection layer 105 are almost even level with the surface of the semiconductor substrate 100. However, the insulating filler layer 111, which has no step difference with respect to the surface of the semiconductor substrate 100, is not always good. Rather, the insulating filler layer 111 may be formed to have a step difference to the surface of the semiconductor substrate 100. For this, the trench 110 may be formed to have a step difference a little higher than the other portions of the semiconductor substrate 100 by adjusting the thickness of the insulating mask layer 103, the polished degree of the insulating mask layer 103, the thickness of the pad oxide layer 101, and the degree to which the pad oxide layer 101 is etched.

As described above, the isolation method for a semiconductor device in at least one exemplary embodiment of the present invention is capable of reducing the possibility of dents occurring along the edge of the trench 110 by forming the sidewall oxide layer 107 to a desired thickness at the sidewall of the insulating mask layer 103. In addition, according to the isolation method for a semiconductor device of an exemplary embodiment of the present invention, it is possible to repair damage to the trench 110 and defects caused by trench etch by forming the sidewall oxide layer 107 at a high process temperature (or using a high temperature process), and thus leakage current can be decreased after manufacture of a semiconductor device is completed. Moreover, it is possible to enhance the electrical characteristics of a device by reducing the occurrence of an undesirable phenomenon, such as a hump phenomenon concerning with the threshold voltage in I-V curve.

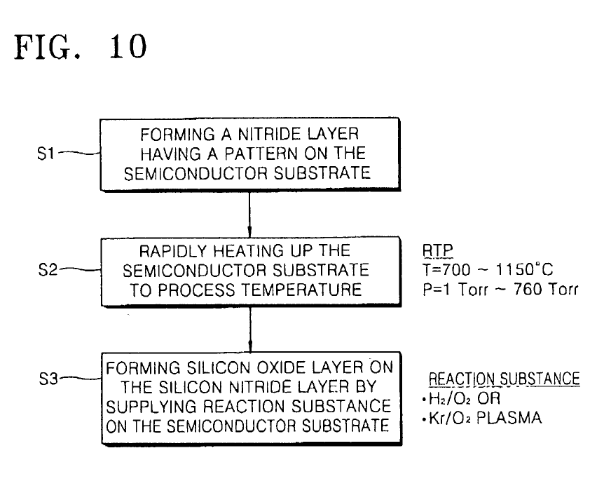

FIG. 10 is a unit process flow chart illustrating a step of forming a silicon oxide layer on a silicon nitride layer through thermal oxidation in the isolation method for a semiconductor device of an exemplary embodiment of the present invention. As shown in FIG. 10, a nitride layer having a pattern is formed on a semiconductor substrate in step s1. The semiconductor substrate is rapidly heated to a desired process temperature in a high temperature reactor or a high temperature reaction chamber in step s2. A silicon oxide layer is formed to a desired thickness on the silicon nitride layer by injecting a reaction substance (an element), which reacts with silicon to form an oxide layer, such as an oxidation gas, and making the reaction material contact with the semiconductor substrate in step s3.

In an exemplary embodiment, the process temperature required to heat the semiconductor substrate is set to a range between 700° C. and 1100° C., and additionally, the pressure of the reactor or reaction chamber may be set to a range between 1 torr and 760 torr.

The oxidation gas may be a mixed gas of oxygen (O₂) and hydrogen (H₂) having an appropriate O₂:H₂ ratio. In an exemplary embodiment, the volume of the H₂ gas may be adjusted to be smaller than that of the O₂ gas, and thus the volume ratio of the H₂ gas to the mixed gas may be 1-50%, in consideration for the probability of abrupt explosion.

In order to supply the oxidation gas as a plasma type, a reaction gas containing Kr and oxygen O₂ gas may be injected into a plasma reaction chamber, and thus the oxygen gas is converted into oxygen plasma. The oxygen plasma is supplied to the semiconductor substrate. Then, a reaction between the silicon nitride layer and the oxygen plasma can be induced more easily and thus a silicon oxide layer can be formed more quickly through the reaction.

A silicon oxide layer by oxidizing a polycrystalline silicon formed by chemical vapor deposition, instead of an oxide layer formed by thermal oxidation or chemical vapor deposition used in exemplary embodiments of the present invention, may be used for the sidewall oxide layer 107.

Instead of a silicon nitride layer in exemplary embodiments the present invention, boron nitride (BN) or an aluminium oxide (Al₂O₃) layer may be used for the trench liner layer 109. BN may be formed by low pressure chemical vapor deposition (LP CVD) or atomic layer deposition (ALD), which is a type of photo chemical vapor deposition. However, since the trench liner layer 109 must be thinly formed, the BN may be formed by ALD. Also, in the case of forming an aluminium oxide layer as the trench liner layer 109, ALD may be used.

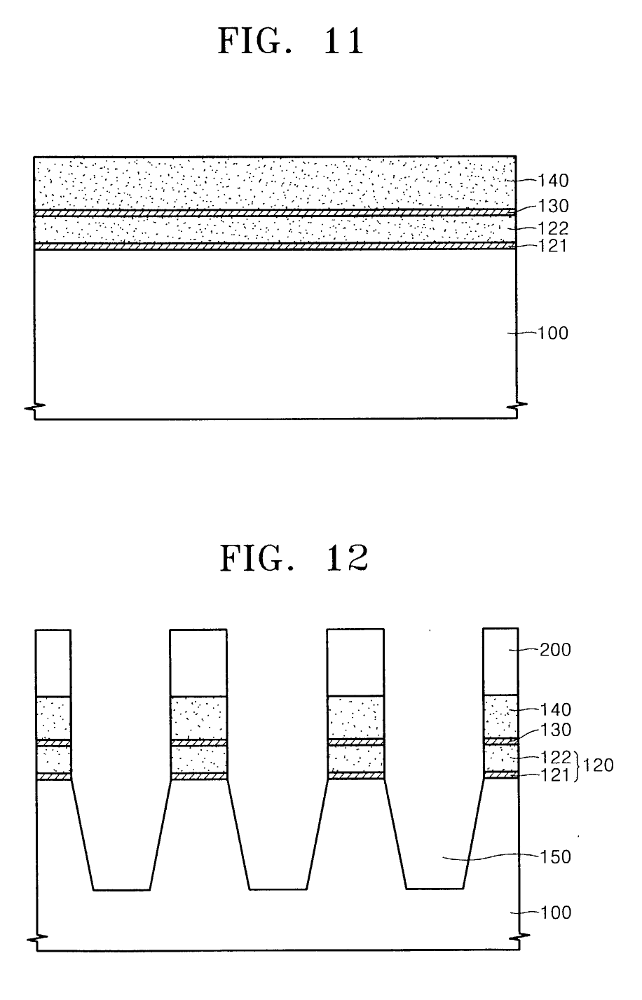

FIGS. 11 through 18 are cross-sectional views illustrating a method for manufacturing a semiconductor device according to another exemplary embodiment of the present invention. For discrimination between the above-mentioned exemplary embodiment and this exemplary embodiment, other elements with other reference numerals exclusive of reference numerals for a semiconductor substrate will be described below.

Referring to FIG. 11, a gate insulating layer 121 is formed on the semiconductor substrate 100 onto which the silicon is exposed. Here, a silicon nitride layer, in which a silicon oxide layer is nitrified by a nitrogen source gas, as well as a silicon oxide layer can be used for the gate insulating layer 121.

After formation of the gate insulating layer 121, a gate conductive layer 122 is formed on the gate insulating layer 121. The gate conductive layer 122 is a layer having given conductivity, and polycrystalline silicon to which phosphorous (P) or Arsenic (As) is doped, may be used for the gate conductive layer 122. The gate conductive layer 122 may be formed using low pressure chemical vapor deposition (LP CVD), and impurities may be in-situ doped by supplying a silicon source gas and a phosphorous (P)-doped source gas to the semiconductor substrate 100 at a time, resulting in a simple process and the uniform concentration of doping.

The gate conductive layer 122 may be formed by combining metal silicide having lower sheet resistance (Rs) such as tungsten silicide (WSi), titanium silicide (TiSi), or cobalt silicide (CoSi), when the characteristics no greater than sheet resistance (Rs), which is obtained by doping impurities such as phosphorous (P), to polycrystalline silicon, are required.

After formation of the gate conductive layer 122, a silicon nitride layer is formed as an insulating mask layer 140 on the gate conductive layer 122. Since a layer will be thickly etched when a gate pattern and a trench pattern are etched, the silicon nitride layer may serve as a protection layer so that physical collision with plasma exposed for a long time and damages caused by shock of electrical power in etching are reduced. A layer to be etched is thick, photoresist doesn't remain as a mask layer until a trench is etched, and thus the silicon nitride layer may also serve as an etch mask. The insulating mask layer 140 is formed as a layer, which applies less stress to the gate conductive layer 122 formed under the insulating mask layer 140 or, further to the silicon of the semiconductor substrate 100, even if the insulating mask layer 140 is formed to be thicker than a layer having superior mechanical characteristics due to high density and great hardness of the insulting mask layer 140. Thus, a silicon nitride layer may be formed by plasma enhanced CVD using plasma. The silicon nitride layer (Si₃N₄) may also be formed by LP CVD when a layer requires cleanness or hardness.

In this way, the gate insulating layer 121, the gate conductive layer 122, and the insulating mask layer 140 are sequentially formed on the semiconductor substrate 100. In a case where the gate conductive layer 122 and the insulating mask layer 140 are formed in contact with each other of polycrystalline silicon and a silicon nitride layer, respectively, due to an excellent adhesive property, the gate conductive layer 122 may be damaged by a polycrystalline silicon used as an underlying layer in a subsequent process for stripping the insulating mask layer 140. Thus, a silicon oxide layer formed by CVD may be interposed between the gate conductive layer 122 and the insulating mask layer 140 as an insulating buffer layer 130, and a silicon nitride layer is formed on the silicon oxide layer as the insulating mask layer 140. A mid-temperature oxide (MTO) layer, a TEOS oxide layer, or a high temperature oxide (HTO) layer, which are formed using LP CVD, as a silicon oxide layer, may be used for the insulating buffer layer 130.

Referring to FIG. 12, the insulating mask layer 140 is coated with photoresist 200, and gate and trench patterns are formed on the photoresist 200 through alignment exposure and developing processes. First, the gate and trench patterns are formed by dry etching in the insulating mask layer 140 formed of a silicon nitride layer, using the photoresist 200 on which the gate and trench patterns are formed, as a mask. The underlying insulating buffer layer 130 as a silicon oxide layer, and the gate conductive layer 122 are sequentially dry-etched using the photoresist 200 as a mask, and the gate and trench patterns are transferred as a mask, thereby forming a gate 120. In such a case, the gate insulating layer 121 is completely removed by over etching, and the silicon 101 of the semiconductor substrate 100 is etched to a desired depth, using the remaining photoresist 200 and the insulating mask layer 140 as a mask, thereby forming a trench 150 recessed downward to the silicon 101. After that, the remaining photoresist 200 and polymers occurring during trench etching may be are removed by wet cleaning. In this way, the gate 120 and a trench 150 for isolating individual devices may be simultaneously formed on the semiconductor substrate 100.

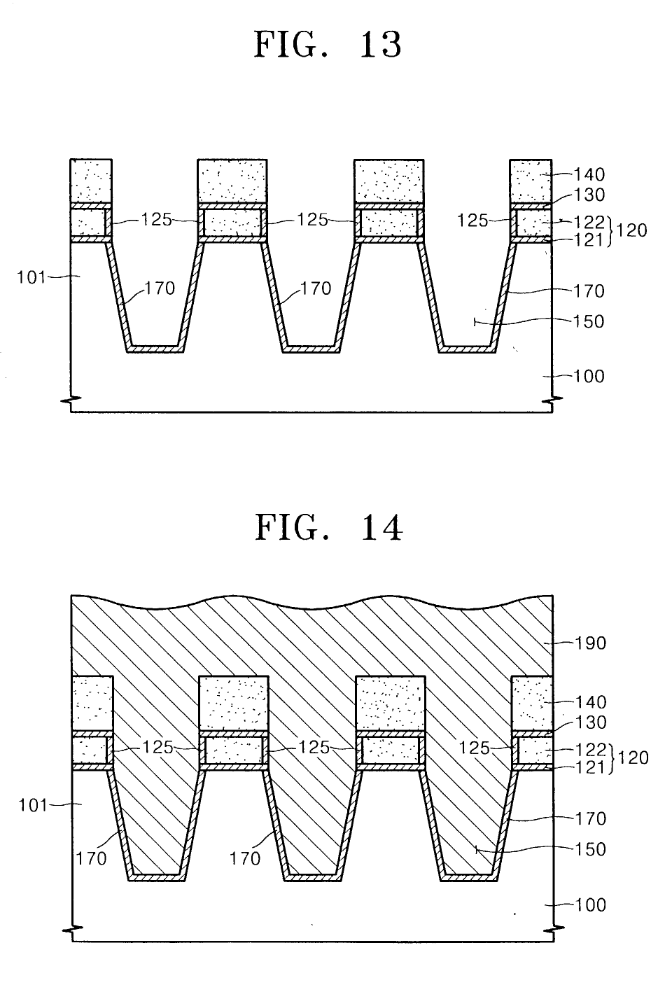

Referring to FIG. 13, a liner insulating layer 170 is formed on the sidewall of the trench 150 to which the silicon 101 is exposed, and a gate sidewall insulating layer 125 are formed on a sidewall of the gate 120 to which the gate conductive layer 122 is exposed. The liner insulating layer 170 and the gate sidewall insulating layer 125 are formed of a silicon oxide layer by thermal oxidation. The liner insulating layer 170 and the gate sidewall insulating layer 12 may be formed simultaneously. The liner insulating layer 170 and the gate sidewall insulating layer 125 are formed by an oxidation reaction of a selected oxidation gas, which is supplied to the sidewall of the trench 150, to which the silicon 101 is exposed, and to the sidewall of the gate 120 by heating the semiconductor substrate 100 at a desired temperature, with silicon. The oxidation gas may be a mixed gas of hydrogen (H₂) and oxygen (O₂) and causes wet and dry oxidation reactions with the silicon exposed on the semiconductor substrate 100 to from a silicon oxide layer (SiO₂). Thus, the silicon oxide layer has both the characteristics caused by dry oxidation and wet oxidation. The semiconductor substrate 100 may be heated through rapid thermal processing requiring a short time of about from several seconds to several tens of seconds so as to increase to a desired process temperature such that a process time and thermal budget, which is accumulated on the semiconductor substrate 100, are reduced. A process temperature for forming an oxide layer depends on the thickness of a silicon oxide layer to be formed, but an oxide layer is formed at a comparatively high temperature between 800° C. and 1150° C., thereby improving the characteristics of the oxide layer. In a case where the gate sidewall insulating layer 125 and the liner insulating layer 170 as a silicon oxide layer, are thinly formed, the growth rate of the oxide layer is high, and thus it is difficult to control the thickness and uniformity of the oxide layer, and the oxide layer is formed at a low pressure between 0.1 torr and 700 torr to reduce its growth rate. In this way, the sidewall of the insulating layer used as a mask is oxidized, thereby reducing a bird's beak phenomenon occurring at an interface between the upper portion of the gate and the insulating mask layer 140.

Referring to FIG. 14, a thick insulating filler layer 190 is formed on the semiconductor substrate 100 to fill a trench 150. The insulating filler layer 190 may be a silicon oxide layer formed by CVD using LP CVD or plasma.

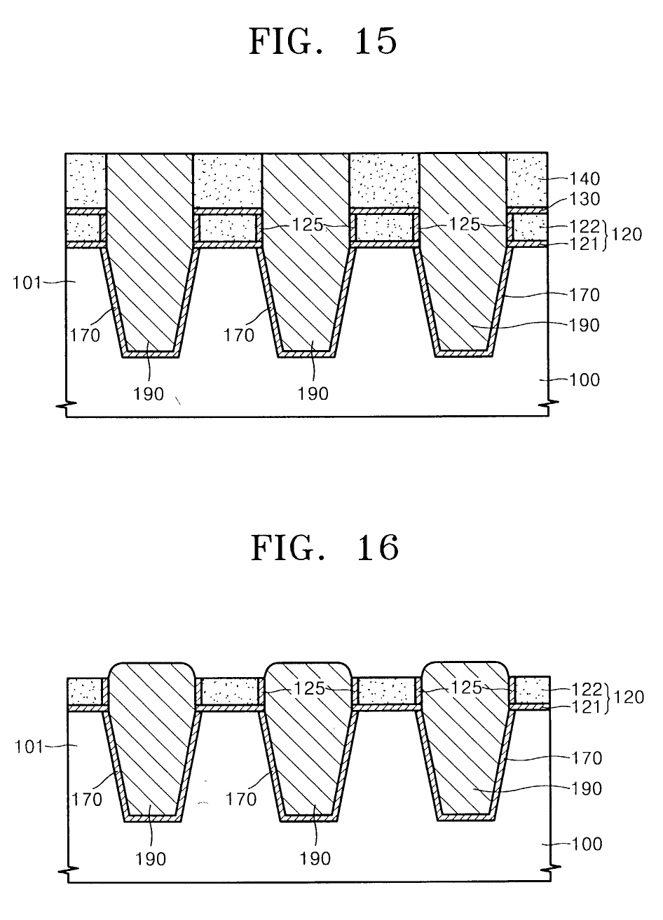

Referring to FIG. 15, the insulating filler layer 190 formed on the semiconductor substrate 100 is removed to a desired thickness by a planarization process. As shown in FIG. 15, chemical mechanical polishing is performed on the upper portion of the insulating mask layer 140 by using the insulating mask layer 140 as a polishing stopper to polish the insulating filler layer 190, thereby leaving the insulating filler layer 190 only in a trench region for isolating individual devices.

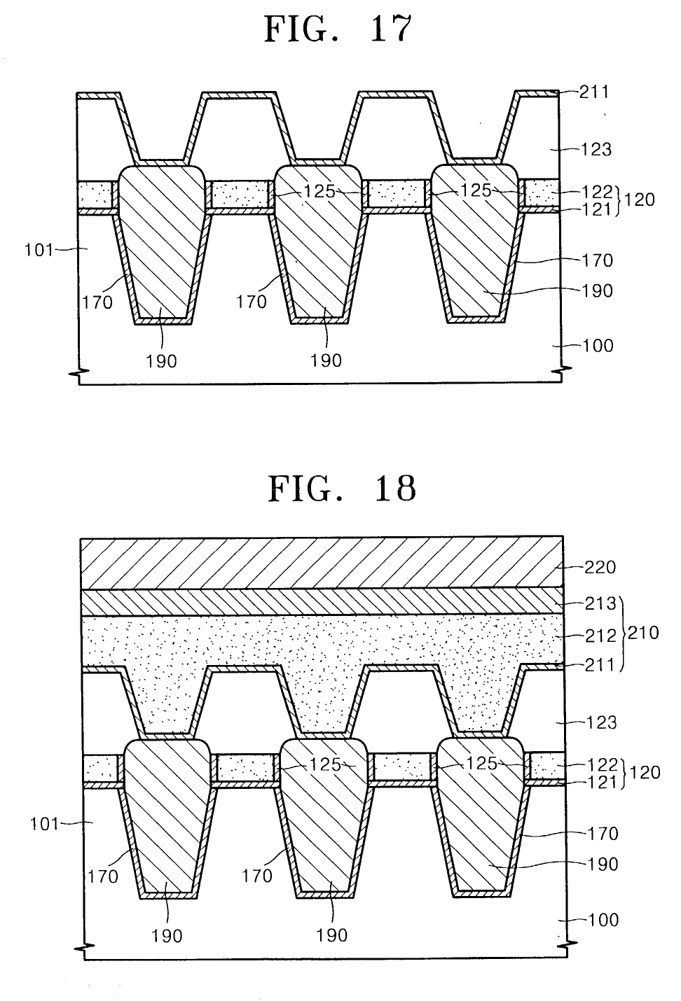

Referring to FIG. 16, the insulating filler layer 190, the insulating mask layer 140, and the insulating buffer layer 130 are removed evenly to a portion adjacent to the top surface of the gate 120, and the insulating mask layer 140 remaining on the gate 120 is selectively removed to expose the top surface of the gate 120. The insulating mask layer 140 may be removed to the top surface of the gate 120 in at least two different ways.

A first way is that the insulating mask layer 140 formed of a silicon nitride layer (Si₃N₄) is completely removed by wet etching using a phosphoric acid (H₃PO₄) solution at a high temperature and then, the insulating buffer layer 130 formed of a silicon oxide layer (SiO₂) is removed by wet etching using a fluoric acid solution, such as HF or buffered HF (BHF).

The second way is that the insulating mask layer 140 formed of a silicon nitride layer is removed by dry etching, and the insulating buffer layer 130 is removed by wet etching. Then, the top surface of the gate 120 is exposed to the semiconductor substrate 100, and the insulating filler layer 190 is planarized in an isolation region in which the trench 150 is formed, by forming a step difference with the top surface of the gate 120.

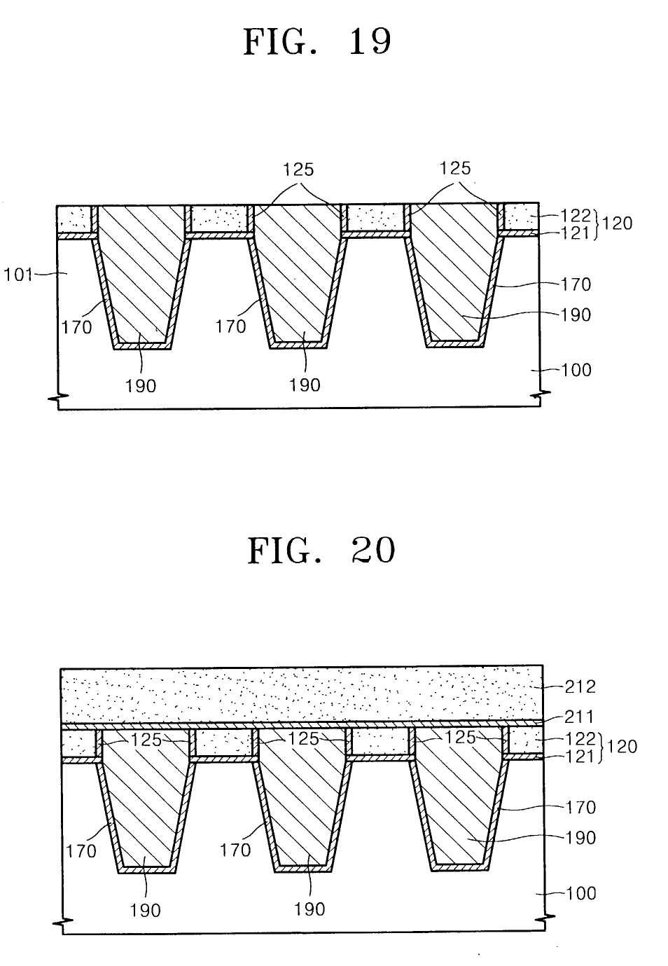

Referring to FIG. 17, impurity-doped polycrystalline silicon as a conductive material, is deposited on the top surface of the gate 120. An intermediate gate 123 is formed using processes for forming patterns, such as a photolithographic process and a dry etching process, on the conductive material. A dielectric layer 211 is formed on the surface of the intermediate gate 123 as an insulating layer. The dielectric layer 211 depends on the characteristics of devices but is generally formed of a silicon oxide layer or silicon nitride layer. However, in a case where a high dielectric constant between the gate 120 and a second gate 210 due to the characteristics of a flash memory device is required, a high dielectric layer formed of a high dielectric material such as Ta₂O₅, PLZT, PZT or BST, which may be applied to a capacitor in a dynamic random access memory (DRAM) may be used.

Referring to FIG. 18, a second gate conductive layer 212 is formed on the dielectric layer 211.

The second gate conductive layer 212 may be formed of polycrystalline silicon, which is formed by doping phosphorous (P) or Arsenic (As) as impurity, so as to have conductivity. The second gate conductive layer 212 may be formed by LP CVD through in-situ impurity doping. In a case where the second gate conductive layer 212 requires a lower sheet resistance, the doped polycrystalline silicon may not be sufficient, and thus polycide, which is formed by combining metal silicide having a lower resistivity, can be applied. That is, the metal silicide is formed through self-aligned silicidation for forming TiSi, MoSi, NiSi, or CoSi, by letting the metal silicide to be thermally reacted only on a gate to which the silicon is exposed by depositing titanium (Ti), molybdenum (Mo), nickel (Ni), or cobalt (Co), on the second gate 210 on which patterns have been already formed, and by performing thermal treatment at a desired temperature. WSi may be deposited and formed through metal CVD.

The second gate conductive layer 212 is coated with photoresist (not shown), and the second gate 210 is formed through a photolithographic process and a dry etching process. After that, a subsequent process for forming sources and drains is performed, and then an interlevel dielectric (ILD) layer 220, a contact (not shown), and a bit line (not shown) are sequentially formed. The bit line is formed by combining an impurity-doped polycrystalline silicon 231 having conductivity with a tungsten silicide layer 232. A semiconductor device is completed through a process for forming the ILD layer 220 by contact formation, a metal interconnection process, and a plurality of metal interconnection processes, as occasion demands.

FIGS. 19 through 21 are cross-sectional views illustrating a method for manufacturing a semiconductor device according to another exemplary embodiment of the present invention. The exemplary method shown in FIGS. 11 through 15 is similar to the exemplary method, and subsequent processes will be described below.

Referring to FIG. 19, the insulating filler layer 190, the insulating mask layer 140, and the insulating buffer layer 130 are removed evenly to the top surface of the gate 120 to expose the top surface of the gate 120. The insulating mask layer 140 and the insulating buffer layer 130 may be removed to the top surface of the gate 120 in at least three different ways.

A first way is that the insulating filler layer 190 is removed through CMP as shown in FIG. 15, the silicon nitride layer and the silicon oxide layer are removed at the same polishing rate by varying a polishing slurry for CMP. The insulating filler layer 190 and the insulating buffer layer 130 are removed to the top surface of the gate 120 in one process, thereby exposing and planarizing the gate 120 at a time. The insulating buffer layer 130 formed of a silicon oxide layer is polished and removed by using the gate 120 formed of polycrystalline silicon as a polishing stopper to expose the top surface of the gate 120.

A second way is a two-step process and the insulating mask layer 140 formed of a silicon nitride layer is removed by wet etching using phosphoric acid (H₃PO₄) solution. Dry etching using a recipe having a high selectivity with respect to a silicon oxide layer and a silicon nitride layer may be used so as to selectively remove the silicon nitride layer. Then, an uneven silicon oxide layer pattern is formed in a place where the insulating mask layer 140 is removed. In this state, the insulating filler layer 190 and the insulating buffer layer 130 are evenly polished until the top surface of the gate 120 is exposed by CMP using a polishing slurry for polishing a silicon oxide layer. The gate conductive layer 122 formed of polycrystalline silicon is used as a polishing stopper. Then, the top surface of the gate 120 is exposed, and the insulating filler layer 190 is planarized to the top surface of the gate 120 in the isolation region in which the trench 150 is formed.

A third way is that a polishing slurry for polishing a silicon oxide layer and a silicon nitride layer at the same polishing rate is used when the insulating filler layer 190 shown in FIG. 15 is polished by CMP. Thus, as shown in FIG. 7, the insulating filler layer 190, the insulating mask layer 140, and the insulting buffer layer 130 are polished to the top surface of the gate 120 in a one-step process.

Referring to FIG. 20, the dielectric layer 211 is formed on the top surface of the gate 120 as an insulating layer, and the second gate conductive layer 212 is formed on the dielectric layer 211. The dielectric layer 211 depends on the characteristics of devices but is generally formed of a silicon oxide layer or silicon nitride layer. However, in a case where a high dielectric constant between the gate 120 and the second gate 210 due to the characteristics of a flash memory device is required, a high dielectric layer formed of a high dielectric material such as Ta₂O₅, PLZT, PZT or BST, which may be applied to a capacitor of dynamic random access memory (DRAM) may be used.

The second gate conductive layer 212 may be formed of polycrystalline silicon, which is formed by doping phosphorous (P) or Arsenic (As) as an impurity, so as to produced conductivity. The second gate conductive layer 212 may be formed by LP CVD through in-situ impurity doping. In a case where the second gate conductive layer 212 requires a lower sheet resistance, the doped polycrystalline silicon may not be sufficient, and thus polycide, which is formed by combining metal silicide having a lower resistivity, can be applied to the case. That is, the metal silicide is formed through self-aligned silicidation for forming TiSi, MoSi, NiSi, or CoSi, by letting the metal silicide to be thermally reacted only on a gate to which the silicon source is exposed by depositing titanium (Ti), molybdenum (Mo), nickel (Ni), or cobalt (Co), on the second gate 210 on which patterns have been already formed, and by performing thermal treatment at a desired temperature. WSi may be deposited and formed through CVD.

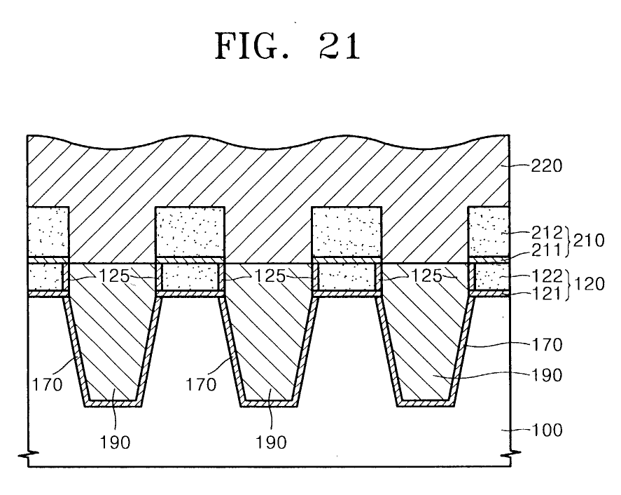

Referring to FIG. 21, like in FIG. 18, the second gate conductive layer 212 is coated with photoresist (not shown), and the second gate 210 is formed through a photolithographic process and a dry etching process. After that, a subsequent process for forming sources and drains is performed, and then the interlevel dielectric (ILD) layer 220, a contact (not shown), and a bit line (not shown) are sequentially formed. The bit line is formed by combining the impurity-doped polycrystalline silicon 231 having conductivity with the tungsten silicide layer 232. A semiconductor device is completed through a process for forming the ILD layer 220 b contact formation, a metal interconnection process, and a plurality of metal interconnection processes, as occasion demands.

In the method for isolating individual devices for a semiconductor memory device having the above structure according to exemplary embodiments of the present invention, since rapid thermal processing having a short process time is used when the gate sidewall oxide layer 125 is formed on the sidewall of the gate 120, a distance where an oxidation gas is penetrated into an interface during formation of an oxide layer, can be reduced such that a bird's beak that grows along an interface between the insulating buffer layer 130 and the gate 120, and the gate insulating layer 121 interposed between the gate 120 and the silicon can be reduced. The gate sidewall oxide layer 125 is formed, and simultaneously the insulating mask layer 140 formed of a silicon nitride layer is oxidized, and thus the oxidation of polycrystalline silicon of the gate conductive layer 122 is more uniformly performed, and morphology of the gate sidewall oxide layer 125 is evenly performed, and thus defects caused by bridge with neighboring cells can be reduced.

Rapid thermal processing has been used in a junction thermal treatment process for ion activation. However, since the temperature of a semiconductor substrate is comparatively unstable during rapid thermal processing, it is difficult to form a uniform film layer by a rapid thermal processor (RTP), and thus the rapid thermal processor has not been used for forming a layer. However, recently, owing to the outstanding development of the RTP, that is, the configuration of the RTP has developed into a single chamber type, and the semiconductor substrate is rotated for uniform temperature uniformity, more uniform temperature distribution has been achieved.

Further to this, a method for supplying a reaction gas has been improved, that is, the method can be applied to a semiconductor device to form a uniform film layer, and the uniform film layer can be obtained by rapid thermal oxidation. That is, hydrogen (H₂) and oxygen (O₂) are used for an oxidation reaction gas such that the hydrogen (H₂) and oxygen (O₂) flow into a reactor or chamber, and vaporizing water (H₂O) is generated and reacts with silicon to form a wet oxide layer, the characteristics of the wet oxide layer are improved, and there is little difference in the growth rate regardless of a reaction element (substance) such as silicon or polycrystalline silicon, and there is little difference between the thickness of the oxide film layer and the thickness of the liner insulating layer 170, which is formed by oxidizing the silicon of a substrate in a trench, or the thickness of the gate sidewall insulating layer 125, which is formed by oxidizing the polycrystalline silicon, and thus, the wet oxide layer is formed to a substantially uniform thickness.

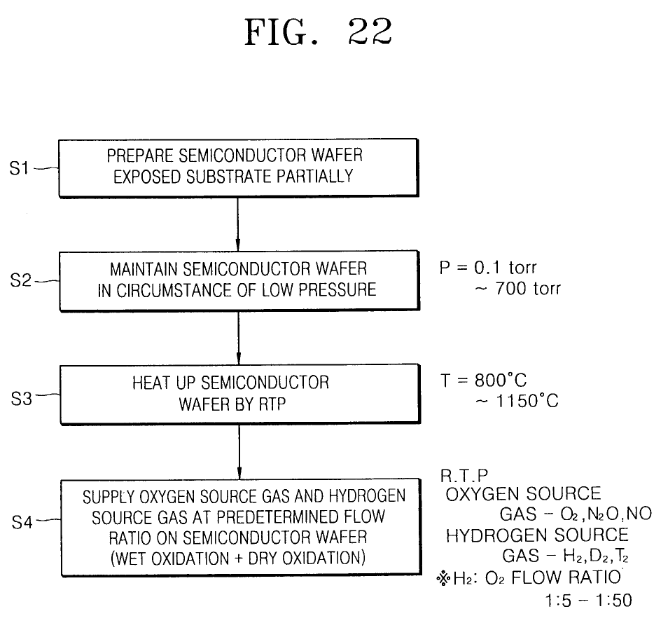

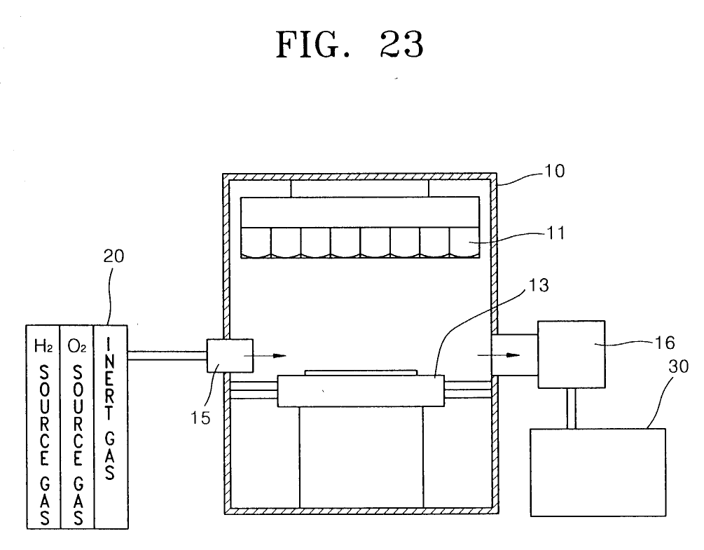

FIG. 22 is a unit process flow chart illustrating a method for forming a silicon oxide layer on the sidewall of a gate of a semiconductor memory device according to another exemplary embodiment of the present invention, and FIG. 23 is a schematic view illustrating a rapid thermal processor (RTP) used for forming a silicon oxide layer according to an exemplary embodiment of the present invention.

Referring to FIGS. 22 and 23, after a trench is etched, or a gate pattern is etched, a semiconductor substrate (100 of FIG. 1) on which at least one of a part of polycrystalline silicon on the sidewall of a gate and a part of the silicon substrate in the trench are simultaneously exposed, is provided. The semiconductor substrate (100 of FIG. 1) is put on a wafer supporter 13 in a reaction chamber (10 of FIG. 23), a desired low pressure is maintained in the reaction chamber 10 through a vacuum system (30 of FIG. 23), and rapid thermal processing is performed on the semiconductor substrate 100 through a heater (11 of FIG. 23) comprised of a radiation lamp, so as to rapidly increase temperature. Then, a hydrogen source gas and an oxygen source gas are simultaneously supplied in a desired ratio to the semiconductor substrate 100 through a gas supplier 20, a gas inlet 15, and the reaction chamber 10. Then, the hydrogen source gas and the oxygen source gas react near the semiconductor substrate, and vaporizing water (H₂O) and O₂ radical are generated such that the silicon and polycrystalline silicon, which are exposed on the semiconductor substrate 100, are simultaneously wet-oxidized and dry oxidized to form a silicon oxide layer to a desired thickness. Reference numeral 16 of FIG. 23 denotes a gas outlet in which remaining gases after the reaction are exhausted.

In an exemplary embodiment of the present invention, oxygen (O₂) is used for the oxygen source gas, and hydrogen (H₂) is used for the hydrogen source gas. The oxidation reaction gases are supplied to the flow ratio of hydrogen to oxygen between 1:50 and 1:5 so that the oxygen is supplied still more than the hydrogen. The hydrogen gas may be supplied at the speed between 0.1 slm and 2 slm.

The reaction chamber 10 is at a low pressure between 0.1 torr and 700 torr. This is the reason the design rule of the semiconductor device becomes finer, and thus an oxide layer is thinly formed, and the growth rate should be reduced to process controllability by reducing the oxidation rate.

Since the characteristics of the oxide layer is good only when the temperature must be at a high temperature and an oxidation reaction sufficiently occurs, the temperature increases between 800° C. and 1150° C. In particular, in order to form a good and clean oxide layer having a high density, an oxide layer should be formed at a temperature between 900° C. and 1000° C. Further, since it takes a lot of time for a normal chamber having a resistance type heater to ramp up the process temperature in the chamber to the high temperature and the semiconductor substrate is exposed for a long time at a high temperature, the temperature can be rapidly ramped up or ramped down by using rapid thermal oxidation, and an unnecessary thermal exposure time of the semiconductor substrate can be reduced.

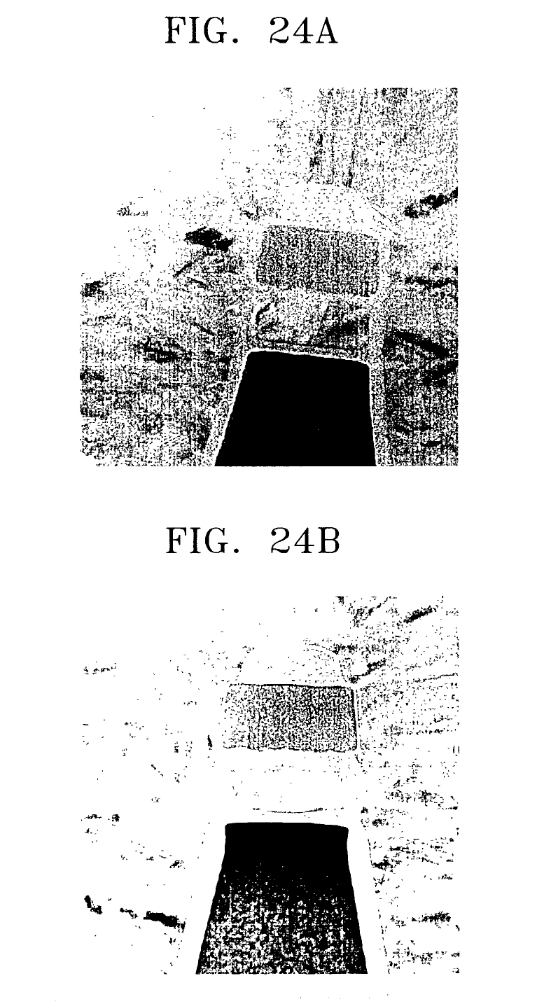

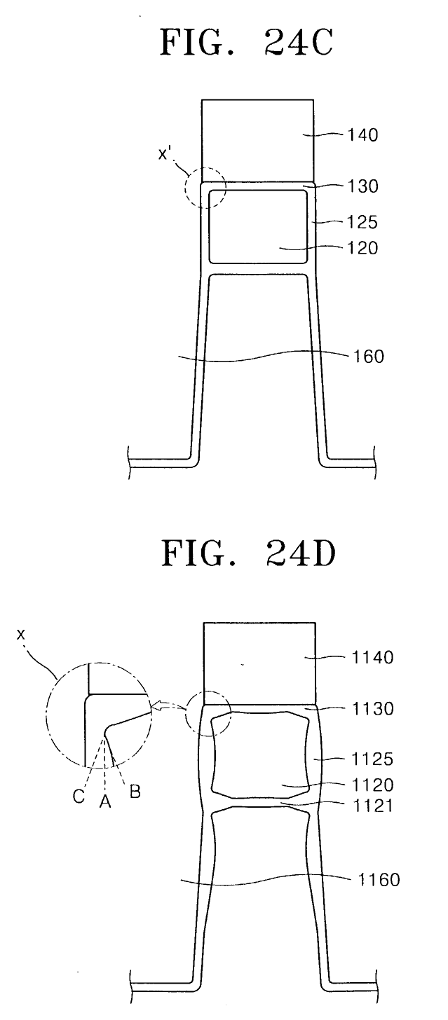

FIGS. 24A and 24B are photographs taken by a scanning electron microscope (SEM), which illustrate a section (FIG. 24A) of gate after formation of a gate sidewall oxide layer according to an exemplary embodiment of the present invention and a section (FIG. 24B) of a gate after formation of a gate sidewall oxide layer in the prior art. FIGS. 24C and 24D are cross-sectional views illustrating FIGS. 24A and 24B for explanation of a difference between FIGS. 24A and 24B.

In a section (FIG. 24A) of a gate according to an exemplary embodiment of the present invention, the size of bird's beaks, which are grown at the interface of the insulating buffer layer 130 between the gate 120 and the insulating mask layer 140 in which a bird's beak phenomenon occurs, is much less than that of FIG. 24B in the prior art.

Referring to FIGS. 24C and 24D, in the prior art, a corner edge X in a patterned gate 1120, or a corner edge where a trench 1160 and a gate insulating layer 1121 intersect, forms an acute angle. The interface of a gate sidewall oxide layer 1125, which is formed at an edge and in a corner where an insulating mask layer intersects, on the basis of the sidewalls of the gate 1120 and the trench 1160 (reverse slope in a case where an interfacial tangent is ‘B’ in comparison with a reference line ‘A’ of FIG. 15D, and fair slope in a case where the interfacial tangent is ‘C’ in comparison with the reference line ‘A’ of FIG. 15D) is formed in a direction ‘B’ on the basis of the reference line ‘A’ and has a reverse sloped shape, and thus negatively affects the electrical characteristics of a completed semiconductor device. That is, electric field is concentrated in an acute corner, the gate insulating layer 1121 is easily broken even in a low operating voltage, and thus the reliability of the gate insulating layer 1121 is deteriorated, and a bird's beak phenomenon occurring at an edge of the gate 1120 causes leakage current, that is, a soft fail. In addition, the slope of the sidewall of the trench 1160 reverses, and an acute corner formed at an edge of the trench 1160 after formation of a liner insulating layer 1170 (silicon oxide layer) may cause a double hump phenomenon of a threshold voltage Vt in I-V curve after formation of junction, and thus the characteristics of the device is deteriorated. However, the size of the bird's beak of the gate sidewall oxide layer 125 according to an exemplary embodiment of the present invention is small, and a corner of the gate sidewall oxide layer 125 is rounded such that the reverse slope of the sidewall of the gate 120 and the trench 160 is reduced. Thus, the electrical characteristics are not deteriorated.

With regard to reactivity, instead of an oxygen source gas and a hydrogen source gas, which are used for a reaction gas, other source gases may be used for a reaction gas. That is, deuterium (D₂) or tritium (T₂) may also be used so as to properly form reactivity as a hydrogen source gas. Since the mass of deuterium (D₂) or tritium (T₂) is larger than that of hydrogen (H₂), a gas is not uniformly supplied to the semiconductor substrate, and a flame reaction with oxygen is not properly performed although a small quantity of deuterium (D₂) or tritium (T₂) due to minor mass is supplied to the semiconductor substrate such that vaporizing water (H₂O) as a substance for wet oxidation, occurs well.

N₂O and NO, instead of oxygen, may be used for an oxygen source gas. When oxygen is used for a source gas, the oxidation rate is high at a high temperature and comparatively high temperature, and thus the uniformity of the oxide layer cannot be guaranteed. However, when N₂O and NO are used for an oxygen source gas, the number of oxygen atoms occurring during reaction is smaller than the number of oxygen atoms occurring when oxygen molecules are dissociated, and thus relatively low growth rate can be anticipated, and the uniformity of the oxide layer may be improved. The oxide layer can be uniformly formed regardless of whether the source is single crystalline silicon or polycrystalline silicon. Thus, a polysilicon residue problem occurring on the sidewall (of gate when depositing the polysilicon and gate patterning in polysilicon in a subsequent process) may be solved.

As describe above, the oxidation reaction gas may include only source gases participating in an oxidation reaction, but an inert gas supplied as a carrier gas SO as to dilute the reaction gases may be further included in the oxidation reaction gas. Nitrogen (N₂), argon (Ar), helium (He) may be used for an inert gas.

The above-mentioned exemplary embodiments of the present invention can be applied to a flash memory, an electrically programmable read only memory (EPROM) or an EEPROM using a double gate similarly to the flash memory. In such a case, a silicon oxide layer or silicon nitride layer instead of a dielectric layer may be used for the insulating layer 211 interposed between the gate 120 (floating gate) and the second gate 210 (control gate).

Exemplary embodiments of the present invention can be applied to a conventional semiconductor memory device having only one gate. That is, when exemplary embodiments of the present invention, in which a trench and a gate are simultaneously formed, are is applied to the conventional semiconductor memory device having only a gate, a manufacturing process is performed until the gate 120 is formed, subsequent processes including a process for forming source and drain junction directly without forming the second gate (220 of FIG. 1) after formation of the gate 120 are performed, and the processes may be different from conventional processes.

The isolation method for a semiconductor device according to the exemplary embodiments of the present invention can reduce or prevent dents from occurring along the edge of a trench after the isolation process is completed by forming a sidewall oxide layer at the sidewall of an insulating mask layer on which a trench pattern is formed. In addition, the isolation method for a semiconductor device according to the exemplary embodiments of the present invention can enhance the electrical characteristics of a device concerning leakage current or threshold voltage by alleviating damage or stresses to the trench occurring when forming the sidewall oxide layer at a high temperature during formation of the trench.

The isolation method for a semiconductor device according to the exemplary embodiments of the present invention can suppress the formation of bird's beaks occurring at an interface between the insulating mask layers formed on the gate, by forming the gate sidewall insulating layer on the sidewall of the gate formed simultaneously with an isolation trench pattern, using rapid thermal oxidation. Thus, a uniformity of distribution of the threshold voltage of a memory device occurring by the bird's beaks can be improved, and thus the yield of the semiconductor memory device can be ultimately increased.

Wet oxidation and dry oxidation may be simultaneously performed on the semiconductor substrate by simultaneously supplying the oxygen gas and hydrogen gas as an oxidation gas, and thus the silicon oxide layer having the characteristics of the wet oxide layer as the growth rate of a dry oxide layer or the growth rate less than the dry oxide layer can be formed.

In addition, the isolation method for a semiconductor device according to the exemplary embodiments of the present invention can reduce the number of diffusion processes and a process time by simultaneously forming the liner insulating layer and the gate sidewall insulating layer on the sidewall of the trench such that process throughput can improved, and the productivity of the semiconductor memory device can be improved.

Furthermore, the isolation method for a semiconductor device according to the exemplary embodiments of the present invention can simultaneously oxidize the silicon nitride layer as the insulating mask layer, such that the underlying polysilicon is uniformly oxidized, thereby reducing defects caused by bridges between the semiconductor memory cells.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. An isolation method for a semiconductor device comprising:
a) forming an insulating mask layer pattern on regions of a semiconductor substrate;
b) forming a trench to a desired depth in the semiconductor substrate using the insulating mask layer pattern as a mask;
c) forming an oxide layer on the insulating mask layer pattern and on the sidewall of the trench;
d) forming a trench liner layer on the oxide layer;
e) forming an insulating filler layer in the trench on the semiconductor substrate on which the trench liner layer is formed so as to fill the trench; and
f) removing the insulating mask layer pattern.

2. The method of claim 1, wherein the a) step comprises:
forming a pad oxide layer on the semiconductor substrate; and
forming a silicon nitride mask layer on the pad oxide layer.

3. The method of claim 2, wherein the pad oxide layer is formed by thermally oxidizing the semiconductor substrate.

4. The method of claim 2, wherein the silicon nitride mask layer is formed by low pressure chemical vapor deposition (LP CVD).

5. The method of claim 1, wherein step a) includes:
forming an insulating mask layer on the entire surface of the semiconductor substrate;
coating the insulating mask layer with photoresist;
forming the trench pattern on an photoresist by photolithography; and
forming a trench pattern on the insulating mask layer using the photoresist trench pattern as a mask.

6. The method of claim 5, further comprising:
forming an anti-reflection layer between the step of forming the insulating mask layer and the step of coating the insulating mask layer with photoresist.

7. The method of claim 6, wherein the anti-reflection layer is formed of one of a silicon nitride layer and a silicon oxynitride layer.

8. The method of claim 5, wherein in the step of forming a trench pattern on the insulating mask layer, the insulating mask layer is dry-etched so as to expose a surface of the semiconductor substrate.

9. The method of claim 5, wherein the step of forming a trench pattern in the insulating mask layer includes removing the photoresist.

10. The method of claim 1, wherein step a) includes:
forming a gate insulating layer, a gate conductive layer, and an insulating mask layer in sequence on the semiconductor substrate to which the silicon is exposed; and
patterning the insulating mask layer, the gate conductive layer, and the gate insulating layer to form an insulating mask pattern and a gate.

11. The method of claim 10, wherein step a) further includes forming an insulating buffer layer between the gate and the insulating mask layer.

12. The method of claim 11, wherein the insulating mask layer is a silicon nitride layer formed by CVD, and the insulating buffer layer is a silicon oxide layer.

13. The method of claim 1, wherein step b), the trench is formed by dry etching.

14. The method of claim 1, wherein the depth of the trench is in a range between 0.1 μm and 1 μm.

15. The method of claim 5, wherein after the trench is formed in the semiconductor substrate, the method further comprising:
removing any photoresist remaining after step a).

16. The method of claim 1, wherein between step b) and c), the method further comprising:
forming an oxide protection layer on the sidewall or inner wall of the trench.

17. The method of claim 16, wherein the oxide protection layer is formed by thermal oxidation.

18. The method of claim 16, further comprising:
forming an oxide layer on the oxide protection layer by chemical vapor deposition.

19. The method of claim 1, wherein step c), the oxide layer is formed by thermally oxidizing the surface of the insulating mask layer pattern.

20. The method of claim 19, wherein the step of forming the oxide layer on the surface of the insulating mask layer pattern includes:
heating the semiconductor substrate on which the insulating mask layer pattern is formed to a desired temperature; and
forming an oxide layer to a desired thickness by supplying an oxidation gas on the insulating mask layer.

21. The method of claim 20, wherein the step of heating the semiconductor substrate is performed by rapid thermal processing.

22. The method of claim 20, wherein the step of heating the semiconductor substrate is performed at a temperature between 700° C. and 1100° C.

23. The method of claim 20, wherein the step of forming the oxide layer is performed at a pressure between 0.1 torr and 760 torr.

24. The method of claim 20, wherein the oxidation gas is a mixed gas of oxygen (O₂) and hydrogen (H₂).

25. The method of claim 24, wherein the volume ratio of the hydrogen gas to the total mixed gas is 1-50%.

26. The method of claim 25, wherein the oxygen gas and the hydrogen gas are supplied at the volume ratio between 1:50 and 1:5

27. The method of claim 26, wherein the hydrogen gas is supplied at the flow rate between 0.1 slm and 2 slm.

28. The method of claim 20, wherein the step of forming the oxide layer is performed in a Kr/O₂ plasma atmosphere.

29. The method of claim 18, wherein the oxide layer is formed to a thickness of 20-300 Å.

30. The method of claim 1, wherein step d), the trench liner layer is formed of a silicon nitride layer.

31. The method of claim 30, wherein the silicon nitride layer is formed by low pressure chemical vapor deposition.

32. The method of claim 1, wherein step d), the trench liner layer is formed of boron nitride (BN).

33. The method of claim 32, wherein the BN is formed by one of low pressure chemical vapor deposition (LP CVD) and atomic layer deposition (ALD).

34. The method of claim 1, wherein the trench liner layer is formed of aluminum oxide (Al₂O₃).

35. The method of claim 34, wherein the aluminum oxide is formed by atomic layer deposition (ALD).

36. The method of claim 1, wherein step e) includes:
forming an insulating filler layer in the trench to completely fill the trench;
heat-treating the insulating filler layer so as to density the insulating filler layer; and
planarizing the insulating filler layer while removing the insulating filler layer deposited on the region on which a device will be formed so as to make the insulating filler layer left only in the trench.

37. The method of claim 36, wherein the insulating filler layer is formed of a silicon oxide layer.

38. The method of claim 36, wherein the insulating filler layer is formed by chemical vapor deposition.

39. The method of claim 38, wherein the insulating filler layer is formed by chemical vapor deposition using plasma.

40. The method of claim 36, wherein the step of heat-treating the insulating filler layer is performed at a temperature between 800° C. and 1150° C.

41. The method of claim 40, wherein the step of heat-treating the insulating filler layer is performed in an inert gas atmosphere.

42. The method of claim 36, wherein the step of planarizing the insulating filler layer is performed by chemical mechanical polishing.

43. The method of claim 42, wherein the step of planarizing the insulating filler layer is performed by chemical mechanical polishing using the insulating mask layer as a polishing stopper.

44. The method of claim 1, wherein step f), the insulating mask layer pattern is removed by wet etching.

45. The method of claim 44, wherein the insulating mask layer pattern is etched by phosphoric acid (H₃PO₄) solution.

46. An isolation method for a semiconductor device comprising:
a) forming a gate insulating layer, a gate conductive layer, and an insulating mask layer in sequence on a semiconductor substrate on which silicon is exposed;
b) patterning the insulating mask layer, the gate conductive layer, and the gate insulating layer to form an insulating mask layer pattern and a gate;
c) forming a trench in the silicon of the semiconductor substrate using the insulating mask layer and the gate as a mask;
d) forming a sidewall insulating layer to a desired thickness on the surface of the silicon of the semiconductor substrate exposed in the trench and on the sidewall of the gate conductive layer of the gate using rapid thermal processing; and
e) filling the trench with an insulating filler layer.

47. The method of claim 46, wherein step a) includes forming an insulating buffer layer between the gate conductive layer and the insulating mask layer.

48. The method of claim 47, wherein the insulating mask layer is a silicon nitride layer formed by chemical vapor deposition (LP CVD).

49. The method of claim 47, wherein the insulating buffer layer is a silicon oxide layer.

50. The method of claim 46, wherein step d), the sidewall insulating layer is a silicon oxide layer.

51. The method of claim 50, wherein the silicon oxide layer is oxidized and formed at a process temperature between 800° C. and 1150° C.

52. The method of claim 50, wherein the silicon oxide layer is formed at a low pressure.

53. The method of claim 52, wherein the pressure is between 0.1 torr and 700 torr.

54. The method of claim 50, wherein hydrogen (H₂) gas and oxygen (O₂) gas are simultaneously used when forming the silicon oxide layer.

55. The method of claim 54, wherein the hydrogen gas and the oxygen gas are supplied at the volume ratio between 1:50 and 1:5

56. The method of claim 55, wherein the hydrogen gas is supplied at the flow rate between 0.1 slm and 2 slm.

57. The method of claim 46 further comprising:
forming a second gate on the gate after step e).

58. The method of claim 57, wherein the step of forming a second gate includes:
exposing an upper portion of the gate;
forming a dielectric layer on the surface of the gate;
forming a second gate conductive layer on the dielectric layer; and
forming a second gate pattern on the second gate conductive layer.

59. The method of claim 58, wherein the step of exposing an upper portion of the gate includes:
forming a conductive material on the upper portion of the gate; and
patterning the conductive material to form an intermediate gate.

60. The method of claim 59, wherein the conductive material is impurity-doped polysilicon.

61. The method of claim 60, wherein the dielectric layer is a high dielectric layer.

62. The method of claim 61, wherein the dielectric layer is one of TaO₅, PLZT, PZT, and BST.

63. The method of claim 58, wherein the second gate conductive layer is impurity-doped polysilicon.

64. The method of claim 63, wherein the second gate conductive layer further forms a silicide layer on the doped polysilicon.

65. The method of claim 64, wherein the silicide layer is formed by self-aligned silicidation on the polysilicon.

66. A method for forming a silicon oxide layer on a semiconductor substrate, the method comprising:
a) preparing a semiconductor substrate including regions on which silicon or polysilicon is exposed;
b) maintaining the semiconductor substrate at a low pressure atmosphere;
c) rapid-thermal-heating the semiconductor substrate at a desired process temperature; and
d) supplying a reaction gas containing an oxygen source gas and a hydrogen source gas onto the semiconductor substrate and forming a silicon oxide layer on the regions on which the silicon or polysilicon is exposed, by a combined oxidation reaction of wet oxidation and dry oxidation.

67. The method of claim 66, wherein step a), the exposed region is at least one of the sidewall of a gate and the sidewall of a trench.

68. The method of claim 66, wherein step b), the low pressure is between 0.1 torr and 700 torr.

69. The method of claim 66, wherein step c), the process temperature is between 800° C. and 1150° C.

70. The method of claim 66, wherein d), the reaction gas is a mixed gas of oxygen (O₂) as an oxygen source gas and hydrogen (H₂) as a hydrogen source gas at a desired ratio.

71. The method of claim 70, wherein the oxygen gas and the hydrogen dgas are supplied at the volume ratio between 1:50 and 1:5.

72. The method of claim 71, wherein the oxygen gas is supplied at the flow rate between 1 slm and 10 slm.

73. The method of claim 66, wherein the hydrogen source gas is one of deuterium (D₂) or tritium (T₂).

74. The method of claim 66, wherein the oxygen source gas is one of N₂O and NO.

75. The method of claim 66, wherein the reaction gas further includes an inert atmosphere gas.

76. The method of claim 75, wherein the atmosphere gas is one of nitrogen (N₂), argon (Ar), and helium (He).
